(19) United States
(12) Patent Application Publication
(10) Pub. No.: US 2024/0372324 A1
(43) Pub. Date: Nov. 7, 2024

(54) Wafer-Level Laser Assemblies Having Extended Resonant Cavities

(71) Applicant: Apple Inc., Cupertino, CA (US)

(72) Inventors: Chin-Han Lin, Santa Clara, CA (US); Nicolas Hotellier, Champagnier (FR); Alexander Hein, Munich (DE); Siddharth Joshi, Saint-Egreve (FR); Fei Tan, Sunnyvale, CA (US)

(21) Appl. No.: 18/143,517

(22) Filed: May 4, 2023

(51) Int. Cl. H01S 5/10; H01S 5/02; H01S 5/0237; H01S 5/183

(52) U.S. Cl. CPC H01S 5/1025; H01S 5/021; H01S 5/0215; H01S 5/0237; H01S 5/18347; H01S 5/34

(57) ABSTRACT

A laser assembly includes a set of one or more substrates having a first surface opposite a second surface. The set of one or more substrates defines a resonant cavity extension. The resonant cavity extension extends into the set of one or more substrates from an opening in the first surface. The laser assembly further includes a first reflector disposed within the resonant cavity extension and configured to reflect at least one wavelength of electromagnetic radiation received through the opening back through the opening; a laser having an active region configured to generate the at least one wavelength of electromagnetic radiation; and a second reflector. The active region is disposed in a resonant cavity extending between the first reflector and the second reflector. The resonant cavity includes the resonant cavity extension.

### FIELD

The described embodiments generally relate to vertical cavity surface-emitting lasers (VCSELs) and, more particularly, to vertical extended cavity surface-emitting lasers (VECSELs).

### BACKGROUND

Compared with VCSELs, VECSELs offer various performance benefits. For example, a VECSEL can provide a longer coherence length (e.g., a coherence length suitable for frequency-modulated continuous-wave (FMCW) depth sensing). A VECSEL can also provide a higher beam quality at higher peak optical power. However, despite these benefits of VECSELs, VECSELs have conventionally been costly to produce. A discrete lens defining the extent of a VECSEL's extended resonant cavity typically needs to be aligned with the beam output of a VCSEL, and active alignment of the lens and VCSEL is usually required. This decreases throughput and increases cost. Furthermore, the performance drift of VECSELs during manufacture can be large. VECSELs are also known to have poor mechanical stability and, as a result, poor reliability.

### SUMMARY

Embodiments of the systems, devices, methods, and apparatus described in the present disclosure pertain to wafer-level laser assemblies having extended resonant cavities.

In some embodiments, a laser's resonant cavity may be extended on the laser's front-side, such as, within a resonant cavity extension defined by (e.g., within) a set of one or more substrates to which the laser is mounted. In some embodiments, a laser's resonant cavity may be extended on the laser's back-side, such as, by forming a reflector on an emission surface of a substrate on which the laser is formed. In either set of embodiments, at least one of the reflectors that define the extent of a laser's resonant cavity is positioned apart from an epitaxial stack in which the laser is formed.

In a first aspect, the present disclosure describes a laser assembly. The laser assembly may include a set of one or more substrates having a first surface opposite a second surface. The set of one or more substrates may define a resonant cavity extension. The resonant cavity extension may extend into the set of one or more substrates from an opening in the first surface. The laser assembly may also include a first reflector disposed within the resonant cavity extension and configured to reflect at least one wavelength of electromagnetic radiation; a laser having an active region configured to generate the at least one wavelength of electromagnetic radiation; and a second reflector. The active region may be disposed in a resonant cavity extending between the first reflector and the second reflector. The resonant cavity includes the resonant cavity extension.

In a second aspect, the present disclosure describes another laser assembly. The laser assembly may include a set of one or more silicon substrates defining a resonant cavity extension; a reflector disposed in the resonant cavity extension; a gallium arsenide (GaAs) substrate; and an epitaxial stack on the GaAs substrate. The epitaxial stack may include a distributed Bragg reflector (DBR) and an active region of a laser. The active region of the laser may be disposed within a resonant cavity including the resonant cavity extension and extending between the reflector and the DBR.

In a third aspect, the present disclosure describes another laser assembly. The laser assembly may include a substrate having a first surface on a first side and a second surface on a second side, and a reflector disposed on the first side, on or offset from the first surface. The laser assembly may also include an epitaxial stack on the substrate. The epitaxial stack may define a set of mesas. A mesa of the set of mesas may include a DBR and an active region of a laser. The active region of the laser may be disposed within a resonant cavity extending between the reflector and the DBR. The laser assembly may also include a silicon substrate. The set of mesas may be mechanically attached to the silicon substrate. A set of conductors may be disposed on or in the silicon substrate and may be electrically connected to an anode and a cathode of the laser.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a first example of a laser assembly having a back-side emission laser and a front-side resonant cavity extension;

FIG. 2 shows an example VCSEL that may be used in the laser assembly shown in FIG. 1;

FIG. 3 shows a second example of a laser assembly having a back-side emission laser (e.g., the VCSEL shown in FIG. 2) and a front-side resonant cavity extension;

FIG. 4 shows a third example of a laser assembly having a back-side emission laser (e.g., the VCSEL shown in FIG. 2) and a front-side resonant cavity extension; FIG. 5 shows a first example of a laser assembly having a back-side emission laser (e.g., the VCSEL shown in FIG. 2) and a back-side resonant cavity extension;

FIG. 6 shows a second example of a laser assembly having a back-side emission laser and a back-side resonant cavity extension; and

FIG. 7 shows a third example of a laser assembly having a back-side emission laser and a back-side resonant cavity extension.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

The described embodiments pertain to wafer-level laser assemblies having extended resonant cavities. Although the described embodiments are generally described in terms of VCSELs having extended resonant cavities (i.e., VECSELs), the described techniques may alternatively be applied to other types of surface-emitting lasers, such as horizontal cavity surface-emitting lasers (HCSELs).

In some embodiments, a laser's resonant cavity may be extended on the laser's front-side, such as, within a resonant cavity extension defined by (e.g., within) a set of one or more substrates to which the laser is mounted. In some embodiments, a laser's resonant cavity may be extended on the laser's back-side, such as, by forming a reflector on an emission surface of a substrate on which the laser is formed. In either set of embodiments, at least one of the reflectors that define the extent of a laser's resonant cavity is positioned apart from an epitaxial stack in which the laser is formed.

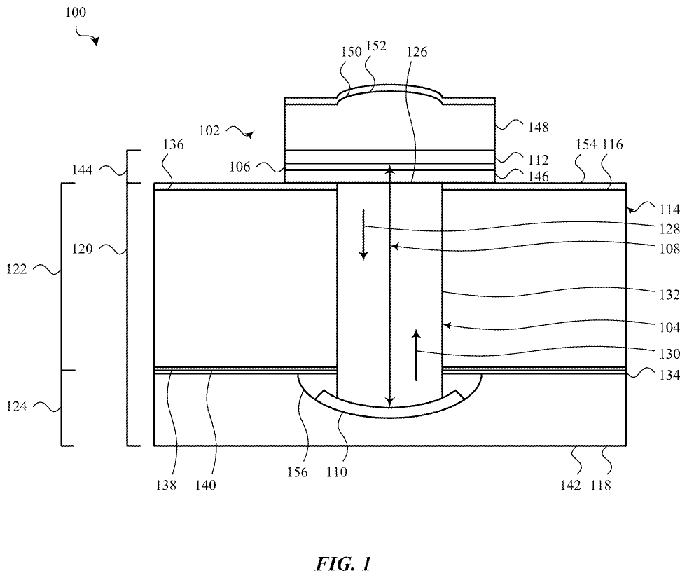

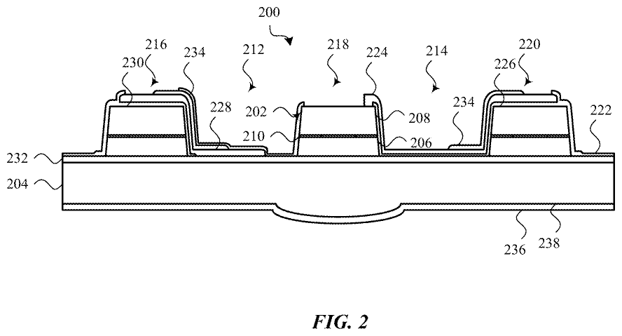

These and other systems, devices, methods, and apparatus are described with reference to FIGS. 1-7. However, those skilled in the art will readily appreciate that the detailed description given herein with respect to these figures is for explanatory purposes only and should not be construed as limiting.

Directional terminology, such as “top,” “bottom,” “upper.” “lower,” “front,” “back,” “over.” “under.” “above,” “below.” “left.” “right.” etc. is used with reference to the orientation of some of the components in some of the figures described below. Because components in various embodiments can be positioned in a number of different orientations, directional terminology is used for purposes of illustration only and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIG. 1 shows a first example of a laser assembly 100 having a back-side emission laser 102 and a front-side resonant cavity extension 104.

In some embodiments, the back-side emission laser 102 (the laser 102) may be a VCSEL. The laser 102 may have an active region 106. The active region 106 may be disposed in a resonant cavity 108 extending between a first reflector 110 and a second reflector 112. The resonant cavity 108 includes the front-side resonant cavity extension 104 (the resonant cavity extension 104).

The resonant cavity extension 104 may extend into (or be defined by) a set of one or more substrates 114 having a first surface 116 opposite a second surface 118. By way of example, the set of one or more substrates 114 may consist of a single substrate 120, or may include a first substrate 122 and a second substrate 124. In some embodiments, the set of one or more substrates 114 may include more than two substrates.

In some embodiments, each of the one or more substrates 114 may be a silicon (Si) substrate. In embodiments that include a first substrate 122 and a second substrate 124, the first substrate 122 may be a fused silica substrate or a silicon carbide (SiC) substrate, and the second substrate 124 may be a Si substrate. In other embodiments that include a first substrate 122 and a second substrate 124, the first and second substrates 122, 124 may have the same or different composition(s). When the first and second substrates 122, 124 have the same composition, and thus the same or similar coefficient(s) of thermal expansion (CTE(s)), thermal mismatch issues can be reduced or eliminated. However, an alternative first substrate 122 (e.g., a SiC substrate) may provide better heat dissipation or other advantages.

The resonant cavity extension 104 may extend into the set of one or more substrates 114 from an opening 126 in the first surface 116. The first reflector 110 may be disposed within the resonant cavity extension 104. The first reflector 110 may be configured to reflect at least one wavelength of electromagnetic radiation. The at least one wavelength of electromagnetic radiation may be received into the resonant cavity extension 104 through the opening 126 (e.g., in a reception direction 128) and be reflected back through the opening 126 (e.g., in a reflection direction 130). The at least one wavelength of electromagnetic radiation may be generated within, and be received back into, the active region 106 (e.g., when a drive signal is applied to the active region 106). When the set of one or more substrates 114 includes two substrates 122, 124, the second substrate 124 may define the first surface 116 and the opening 126, and the first reflector 110 may disposed within the first substrate 122 (as shown) or the second substrate 124, or may be formed spanning both the first substrate 122 and the second substrate 124.

In some embodiments, the first reflector 110 may include one or more layers of dielectric or metal. In some embodiments, the first reflector 110 may be constructed as a DBR. When the set of one or more substrates 114 consists of a single substrate 120 (e.g., a Si substrate), a lens or depression 156 may be etched or otherwise formed in the substrate 120, and then the first reflector 110 may be placed or formed (e.g., deposited) within the lens or depression 156. When the set of one or more substrates 114 includes a first substrate 122 and a second substrate 124 (e.g., two Si substrates), a lens or depression 156 may be etched or otherwise formed in the first substrate 122; the first reflector 110 may be placed or formed (e.g., deposited) within the lens or depression 156; the first substrate 122 may be bonded to the second substrate 124 (e.g., by means of an oxide-to-oxide bond); and a hole 132 (e.g., a through silicon via (TSV) defining the resonant cavity extension 104 may be etched or otherwise formed in the second substrate 124 and aligned with the first reflector 110. In some embodiments, and before the first and second substrates 122, 124 are bonded, an etch stop layer may be formed on the first reflector 110; one or more layers of oxide 134 may be formed on a bonding surface of the first substrate 122 (and in some cases, on the first reflector 110 or etch stop layer); and the layer(s) of oxide 134 may be planarized using a chemical-mechanical polishing (CMP) process. Also in some embodiments, and before the first and second substrates 122, 124 are bonded, various conductors and/or circuitry 154 (e.g., laser diode driver (LDD) circuitry) may be formed on the second substrate 124 (e.g., on a first surface 136 of the second substrate 124 that faces the laser 102); the second substrate 124 may be thinned (e.g., a second surface 138 of the second substrate 124, opposite the first surface 136, may be thinned); and one or more layers of oxide 140 may be formed on a bonding surface (e.g., the second surface 138) of the second substrate. The hole 132 may be formed before or after the first and second substrates 122, 124 are bonded to one another. In some embodiments, the hole 132 is formed by means of a dry etch process, after the first and second substrates 122, 124 are bonded. Optionally, the first substrate 122 may be thinned (e.g., a surface 142 of the first substrate 122 that faces away from the laser 102 may be thinned). The thinning of the first substrate 122 may be performed after the hole 132 is formed or, alternatively, before or after the first and second substrates 122, 124 are bonded to one another. Optionally, the hole 132 may be filled. In some embodiments, the hole 132 may be filled with a polymer. In some embodiments, the hole 132 or resonant cavity extension 104 may fill with air.

In some embodiments, the active region 106 may be formed in one or more layers of an epitaxial stack 144. The epitaxial stack 144 may also include the second reflector 112 (e.g., as a first DBR). Optionally, the epitaxial stack 144 may include a third reflector 146 (e.g., a second DBR) disposed between the active region 106 and the first reflector 110. If included, the second DBR may be weaker than the first reflector 110, so that the first reflector (and not the second DBR) defines the front-side extent of the resonant cavity 108. In some embodiments, the second DBR may only be provided as a current spreading layer and means for current injection.

In some embodiments, the epitaxial stack 144 may be formed on a substrate 148. In some embodiments, the substrate 148 may be a gallium arsenide (GaAs) substrate. Alternatively. the substrate 148 may be an indium phosphide (InP) substrate, a germanium (Ge) substrate, or an indium gallium arsenide (InGaAs) substrate. A lens 150 or other optical element(s) may be defined in, or disposed (e.g., deposited) on, an emission surface 152 of the substrate 148. Additionally or alternatively, and in some embodiments, a lens (e.g., a dielectric lens) or other optical element(s) may be positioned to receive at least one wavelength of electromagnetic radiation generated by the active region 106 of the laser 102. The optical element(s) may include one or more of: gratings; optical beam shapers, tilters, splitters, or filters; and so on. In some embodiments, part or all of the substrate may be removed, or part or all of the substrate on which the epitaxial stack 144 is initially formed may be removed and the epitaxial stack 144 may be bonded to an alternative substrate 148, such as a SiC substrate.

In some embodiments, the laser 102 may be mechanically attached to the set of one or more substrates 114, at least in part, by means of an adhesive or material disposed around the laser 102, or by means of an adhesive or material disposed between the substrate 148 and the set of one or more substrates 114. In some embodiments, the laser 102 may be mechanically attached to the set of one or more substrates 114 (e.g., to the single substrate 120, or to the second substrate 124), at least in part, by means of electrical connections (e.g., solder connections, such as gold solder bumps) made between the laser 102 and conductive bond pads, conductors, and/or circuitry disposed on the set of one or more substrates 114.

Although the laser 102 has been described as a back-side emission laser, and the resonant cavity extension 104 has been described as a front-side resonant cavity extension, the laser 102 could alternatively be a front-side emission laser and the resonant cavity extension 104 could alternatively be a back-side resonant cavity extension.

FIG. 2 shows an example VCSEL 200 that may be used in the laser assembly shown in FIG. 1. The VCSEL 200 may be formed in an epitaxial stack 202 on a substrate 204 (e.g., a GaAs substrate). The epitaxial stack 202 may define a first DBR 206, a second DBR 208, and an active region 210 (e.g., a multiple quantum well (MQW) structure). The active region 210 may be disposed between the first DBR 206 and the second DBR 208. The second DBR 208 is optional and, if provided, the second DBR 208 may be weaker than the first DBR 206. In some embodiments, the second DBR 208 may only be provided as a current spreading layer and means for current injection.

In some embodiments, a single epitaxial stack 202 may be formed on the substrate 204, and then one or more trenches 212, 214 may be etched into (or otherwise formed in) the epitaxial stack 202 to form a set of mesas 216, 218, 220 on the substrate 204. In this manner, each of the mesas 216, 218, 220 may have a same or similar construction and properties. By way of example, three mesas 216, 218, 220 are shown. In other embodiments, more or fewer mesas may be formed. In some embodiments, different mesas may be formed as different epitaxial stacks and/or using different process steps. In some embodiments, some of the mesas may not be formed as epitaxial stacks and may be formed in other ways (e.g., as monolithic blocks of a material).

Some or all of the mesas formed on a substrate may be operable as VCSELs (i.e., lasers). However, in some embodiments, some of the mesas may be operated as photodetectors, or may not be electrically connected to other circuits and may not be operable (or may not be operable as lasers or photodetectors). In FIG. 2, mesa 218 is operable as a VCSEL 200 and mesas 216 and 220 are not operable and only provide mechanical support for mounting the VCSEL 200 to another structure, such as the set of one or more substrates in which the resonant cavity extension is formed in FIG. 1.

As further shown in FIG. 2, one or more layers of dielectric 222, such as one or more layers of SiN or SiO₂, may be deposited on a portion of the substrate 204 between the mesa 216 and the mesa 218, and optionally on a portion of the substrate 204 between the mesa 218 and the mesa 220. The one or more layers of dielectric 222 may also be deposited on walls of the mesas 216, 218, 220. The one or more layers of dielectric 222 may insulate a cathode 224 and an anode 228 of the VCSEL 200 from the mesas 220 and 216. The cathode 224 (e.g., one or more layers of metal) may extend from an upper surface 226 of the mesa 220, along a side of the mesa 220, over the one or more layers of dielectric 222, along a side of the mesa 218, and onto a surface of the epitaxial stack 202 (and more specifically, onto the second DBR 208, on a side of the second DBR 208 opposite the active region 210). The anode 228 (e.g., another one or more layers of metal) may extend from an upper surface 230 of the mesa 216, along a side of the mesa 216, and onto a doped layer 232 of the substrate 204. The doped layer 232 may be conductive, and may extend under the mesa 218 and contact the epitaxial stack 202 of the VCSEL 200. In some embodiments, the doped layer 232 may extend under all of the mesas 216, 218, 220. If the VCSEL 200 is included in an array of VCSELs, the anode 228 may be shared by all of the VCSELs in the array of VCSELs, and each VCSEL may be provided with its own cathode.

In some embodiments, gold (Au) plating 234 may be applied to a portion of the cathode 224 and a portion of the anode 228, to improve the conductivity of the cathode 224 and the anode 228.

The VCSEL 200 may be used as a back-side emission laser, and may emit a primary emission through the substrate 204. In some embodiments, an anti-reflective coating 236 (e.g., one or more layers of SiN and/or SiO₂) may be formed on an emission surface 238 of the substrate 204. Optionally, a lens or other optical element(s) may be defined in, or disposed (e.g., deposited) on, the emission surface 238, and/or a lens (e.g., a dielectric lens) or other optical element(s) may be positioned to receive at least one wavelength of electromagnetic radiation generated by the active region 210 of the VCSEL 200 and emitted through the substrate 204, as described with reference to FIG. 1.

In some embodiments, the VCSEL 200 and its supporting structures may be flipped and bonded to a set of one or more substrates (e.g., as the laser 102 in FIG. 1).

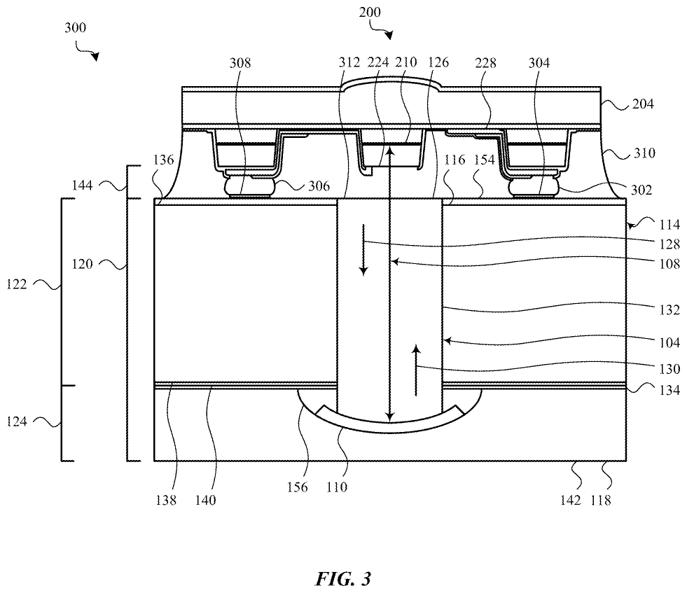

FIG. 3 shows a second example of a laser assembly 300 having a back-side emission laser (e.g., the VCSEL shown in FIG. 2) and a front-side resonant cavity extension. The laser assembly 300 shows the VCSEL 200 and supporting structures described with reference to FIG. 2, flipped and mounted on the first and second substrates 122, 124 described with reference to FIG. 1.

The VCSEL 200 may be aligned with the resonant cavity extension 104 and first reflector 110. A first solder bump 302 (e.g., a first gold solder bump) may mechanically and electrically attach the cathode 224 to a first contact pad 304 on the second substrate 124. The first contact pad 304 may be coupled to a first conductor on or in the second substrate 124. A second solder bump 306 (e.g., a second gold solder bump) may mechanically and electrically attach the anode 228 to a second contact pad 308 on the second substrate 124. The second contact pad 308 may be coupled to a second conductor on or in the second substrate 124.

A dielectric fill material 310 may be disposed around the mesas 216, 218, 220, between the substrate 204 and the second substrate 124 and between the VCSEL 200 and the resonant cavity extension 104. The dielectric fill material 310 may be transparent, or partially transparent, to at least a wavelength of electromagnetic radiation generated by the active region 210. The dielectric fill material 310 may provide further mechanical stability to the VCSEL 200.

In the laser assembly 300, the hole 132 is filled with a polymer 312. The polymer 312 may also be transparent, or partially transparent, to at least a wavelength of electromagnetic radiation generated by the active region 210.

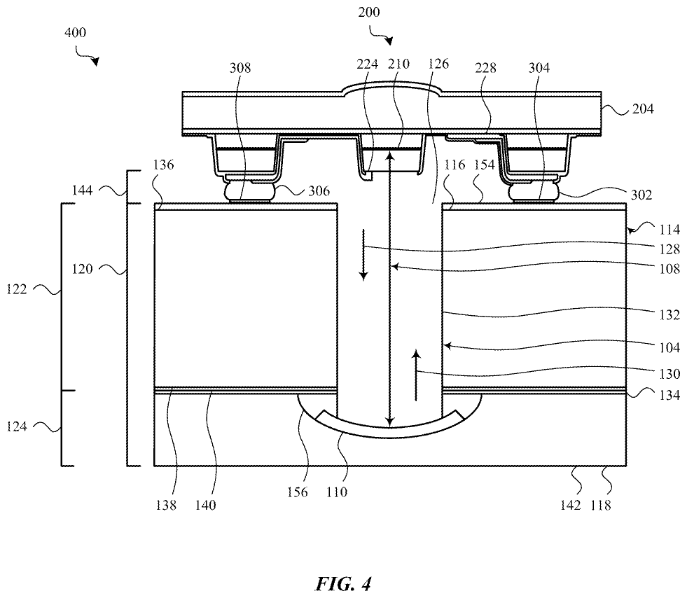

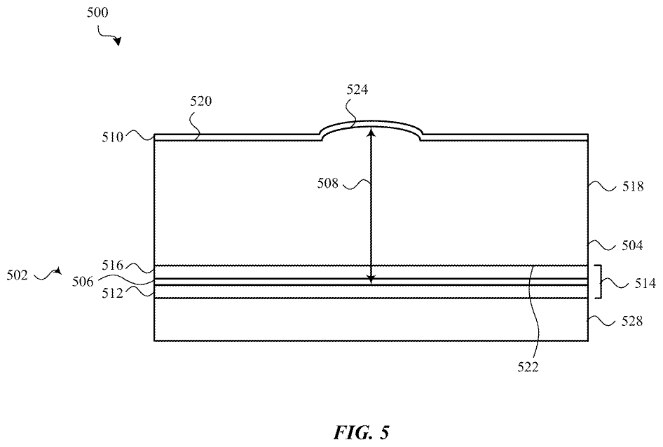

FIG. 4 shows a third example of a laser assembly 400 having a back-side emission laser (e.g., the VCSEL shown in FIG. 2) and a front-side resonant cavity extension. The laser assembly 400 shows the VCSEL 200 and supporting structures described with reference to FIG. 2, flipped and mounted on the first and second substrates 122, 124 described with reference to FIG. 1.

The VCSEL 200 may be aligned with the resonant cavity extension 104 and first reflector 110, and may be mechanically and electrically attached to the second substrate 124 using first and second solder bumps 302, 306 and first and second contact pads 304, 308, as described with reference to FIG. 3. However, in contrast to what is shown in FIG. 3, the laser assembly 400 does not include the dielectric fill material 310 or polymer 312, and the regions occupied by these elements in the laser assembly 300 are filled by air in the laser assembly 400.

FIG. 5 shows a first example of a laser assembly 500 having a back-side emission laser 502 (e.g., the VCSEL shown in FIG. 2) and a back-side resonant cavity extension 504.

In some embodiments, the back-side emission laser 502 (the laser 102) may be a VCSEL. The laser 502 may have an active region 506. The active region 506 may be disposed in a resonant cavity 508 extending between a first reflector 510 and a second reflector 512. The resonant cavity 508 includes the back-side resonant cavity extension 504 (the resonant cavity extension 504).

In some embodiments, the active region 506 may be formed in one or more layers of an epitaxial stack 514. The epitaxial stack 514 may also include the second reflector 512 (e.g., as a first DBR). Optionally, the epitaxial stack 514 may include a third reflector 516 (e.g., a second DBR) disposed between the active region 506 and the first reflector 510. If included, the third reflector 516 (or second DBR) may be weaker than the first reflector 510, so that the first reflector 510 (and not the third reflector 516, or second DBR) defines the back-side extent of the resonant cavity 508. For example, the first reflector 510 may function as a DBR that compensates for the reflection deficit of the third reflector 516 (or second DBR). In some embodiments, the second DBR may only be provided as a current spreading layer and means for current injection. The reflectivities of the first, second, and third reflectors 510, 512, 516 (and especially the first and second (or primary) reflectors 510, 512) may be tuned so that they compensate for the losses in the back-side resonant cavity extension 504. The radius of curvature of the first reflector 510 and/or the length of the back-side resonant cavity extension 504 may also be tuned, such that a stable resonator is formed using the back-side resonant cavity extension 504.

The epitaxial stack 514 may be formed on, or disposed on, a substrate 518. In some embodiments, the substrate 518 may be a GaAs substrate. Alternatively, the substrate 518 may be an InP substrate, a Ge substrate, or an InGaAs substrate. The substrate 518 may have a first surface 520 on a first side of the substrate 518 and a second surface 522 on a second side of the substrate 518. A lens 524 or other optical element(s) may be defined in, or disposed (e.g., deposited) on, the first surface 520. Additionally, and in some embodiments, a lens (e.g., a dielectric lens) or other optical element(s) may be positioned to receive at least one wavelength of electromagnetic radiation generated by the active region 506 of the laser 502 and emitted through the substrate 518. The optical element(s) may include one or more of: gratings; optical beam shapers, tilters, splitters, or filters; and so on. In some embodiments, part or all of the substrate may be removed, or part or all of the substrate on which the epitaxial stack 514 is initially formed may be removed and the epitaxial stack 514 may be bonded to an alternative substrate 518, such as a SiC substrate.

The resonant cavity extension 504 may be defined by the substrate 518, and may extend between the first surface 520 and the second surface 522. The first reflector 510 may be disposed on the first side of the substrate 518, and in some embodiments may be deposited on the first surface 520 of the substrate 518. When deposited on the substrate 518, and in some embodiments, the first reflector 510 may include at least one of SiO₂ or SiN (e.g., one or more layers of SiO₂ and/or SiN). The first reflector 510 may be configured to reflect at least one wavelength of electromagnetic radiation generated by the active region 506. In some embodiments, the first reflector 510 may include one or more layers of dielectric or metal. In some embodiments, the first reflector 510 may be constructed as a DBR.

In some embodiments, the laser 502 may be mechanically attached to a substrate 528. In some embodiments, the substrate 528 may be a Si substrate. The laser 502 may be mechanically attached to the substrate 528, at least in part, by means of an adhesive or material disposed around the laser 502, or by means of an adhesive or material disposed between the substrate 518 and the substrate 528. In some embodiments, the laser 502 may be mechanically attached to the substrate 528, at least in part, by means of electrical connections (e.g., solder connections, such as gold solder bumps) made between the laser 502 and conductive bond pads, conductors, and/or circuitry disposed on the substrate 528.

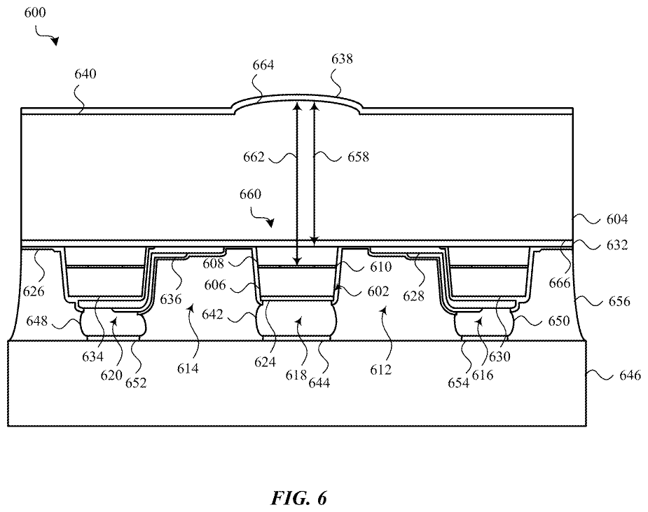

FIG. 6 shows a second example of a laser assembly 600 having a back-side emission laser and a back-side resonant cavity extension 658. The laser assembly 600 is an example of a more detailed implementation of the laser assembly described with reference to FIG. 5. By way of example, the back-side emission laser is a VCSEL 660. The VCSEL 660 may be formed in an epitaxial stack 602 on a substrate 604 (e.g., a GaAs substrate). The epitaxial stack 602 may define a first DBR 606, a second DBR 608, and an active region 610 (e.g., a MQW structure). The active region 610 may be disposed between the first DBR 606 and the second DBR 608. The second DBR 608 is optional and, if provided, the second DBR 608 may be weaker than the first DBR 606 (e.g., as described with reference to FIG. 5). In some embodiments, the second DBR 608 may only be provided as a current spreading layer and means for current injection.

The active region 610 may be disposed in a resonant cavity 662 extending between a reflector 638 (a first reflector) and the first DBR 606 (a second reflector). The resonant cavity 662 includes the back-side resonant cavity extension 658 (the resonant cavity extension 658).

The resonant cavity extension 658 may be defined by the substrate 604, and may extend between the surface 666 and the surface 640. The reflector 638 may be disposed on the first side of the substrate 604, and in some embodiments may be deposited on the surface 640 (i.e., the emission surface) of the substrate 604. When deposited on the substrate 604, and in some embodiments, the reflector 638 may include at least one of SiO₂ or SiN (e.g., one or more layers of SiO₂ and/or SiN). The reflector 638 may be configured to reflect at least one wavelength of electromagnetic radiation generated by the active region 610. In some embodiments, the reflector 638 may include one or more layers of dielectric or metal. In some embodiments, the reflector 638 may be constructed as a DBR.

In some embodiments, a single epitaxial stack 602 may be formed on the substrate 604, and then one or more trenches 612, 614 may be etched into (or otherwise formed in) the epitaxial stack 602 to form a set of mesas 616, 618, 620 on the substrate 604. In this manner, each of the mesas 616, 618, 620 may have a same or similar construction and properties. By way of example, three mesas 616, 618, 620 are shown. In other embodiments, more or fewer mesas may be formed. In some embodiments, different mesas may be formed as different epitaxial stacks and/or using different process steps. In some embodiments, some of the mesas may not be formed as epitaxial stacks and may be formed in other ways (e.g., as monolithic blocks of a material).

Some or all of the mesas formed on a substrate may be operable as VCSELs (i.e., lasers). However, in some embodiments, some of the mesas may be operated as photodetectors, or may not be electrically connected to other circuits and may not be operable (or may not be operable as lasers or photodetectors). In FIG. 6, mesa 618 is operable as a VCSEL 660 and mesas 616 and 620 are not operable and only provide mechanical support for mounting the VCSEL 660 to another structure, such as a substrate 646 containing contact pads, conductors, and/or circuitry 668 (e.g., LDD circuitry).

As further shown in FIG. 6, a cathode 624 of the VCSEL 660 (e.g., one or more layers of metal) may be disposed on a surface of the epitaxial stack 602 (and more specifically, on the second DBR 608, on a side of the second DBR 608 opposite the active region 610). One or more layers of dielectric 626, such as one or more layers of SiN or SiO₂, may be deposited on walls of the mesas 616, 618, 620. The one or more layers of dielectric 626 may also be deposited on a portion of the substrate 604 between the mesa 616 and the mesa 618 and/or on a portion of the substrate 604 between the mesa 618 and the mesa 620. The one or more layers of dielectric 626 may insulate an anode 628 of the VCSEL 660 from the mesas 616 and 620. The anode 628 (e.g., another one or more layers of metal) may extend from an upper surface 630 of the mesa 616, along a side of the mesa 616, and onto a doped layer 632 of the substrate 604. The doped layer 632 may be conductive, and may extend under the mesa 618 and contact the epitaxial stack 602 of the VCSEL 660. In some embodiments, the doped layer 632 may extend under all of the mesas 616, 618, 620. If the VCSEL 660 is included in an array of VCSELs, the anode 628 may be shared by all of the VCSELs in the array of VCSELs, and each VCSEL may be provided with its own cathode. Optionally, the anode 628 may also extend from an upper surface 634 of the mesa 620, along a side of the mesa 620, and onto the doped layer 632 of the substrate 604.

In some embodiments, gold (Au) plating 636 may be applied to a portion of the anode 628, to improve the conductivity of the anode 628.

The VCSEL 660 may be used as a back-side emission laser, and may emit a primary emission through the substrate 604. In some embodiments, an anti-reflective coating (e.g., one or more layers of SiN and/or SiO₂) may be formed on the reflector 638. Optionally, a lens 664 or other optical element(s) may be defined in, or disposed (e.g., deposited) on, the emission surface 640, and/or a lens (e.g., a dielectric lens) or other optical element(s) may be positioned to receive at least one wavelength of electromagnetic radiation generated by the active region 610 of the VCSEL 660 and emitted through the substrate 604, as described with reference to FIG. 5.

A first solder bump 642 (e.g., a first gold solder bump) may mechanically and electrically attach the cathode 624 to a first contact pad 644 on the substrate 646. The first contact pad 644 may be coupled to a first conductor on or in the substrate 646. Second and third solder bumps 648, 650 (e.g., second and third gold solder bumps) may mechanically and electrically attach the anode 628 to respective second and third contact pads 652, 654 on the substrate 646. The second and third contact pads 652, 654 may be coupled to a second conductor on or in the substrate 646 (or to respective second and third conductors on or in the substrate 646).

A dielectric fill material 656 may be disposed around the mesas 616, 618, 620, between the substrate 604 and the substrate 646. The dielectric fill material 656 may be transparent, or partially transparent, to at least a wavelength of electromagnetic radiation generated by the active region 610. The dielectric fill material 656 may provide further mechanical stability to the VCSEL 660.

Coherent optical sensing, including Doppler velocimetry and heterodyning, can be used to obtain spatial information for a target. Example targets include objects, surfaces, particles, and so on. Example spatial information includes presence, distance, velocity, size, surface properties, particle count, and so on. Coherent optical sensing can sometimes be used to obtain spatial information for a target with optical wavelength resolution, at quantum limit signal levels, and with considerably lower photon energy than time-of-flight optical sensing methods. Coherent optical sensing can also limit interference from external aggressors such as ambient light or light generated by light sources of other optical sensing systems.

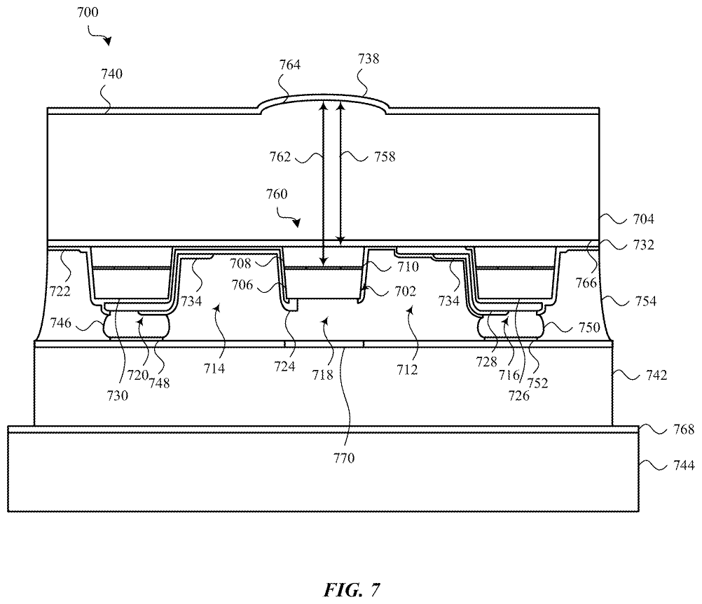

Semiconductor lasers such as VCSELs and VECSELs, integrated with wafer-level or wafer-bonded photodetectors, enable coherent optical sensing using a monolithic sensor structure. For example, a semiconductor laser may generate and emit electromagnetic radiation from a resonant cavity of the semiconductor laser, receive returned (e.g., reflected or scattered) electromagnetic radiation back into the resonant cavity, self-mix the generated and returned electromagnetic radiation within the resonant cavity, and produce an SMI signal that can be detected by an integrated photodetector (e.g., an intra-cavity, stacked, or adjacent photodetector) and used to determine spatial information for a target. An example coherent optical sensor is described with reference to FIG. 7.

FIG. 7 shows a third example of a laser assembly 700 having a back-side emission laser and a back-side resonant cavity extension 758. The laser assembly 700 is an example of a more detailed implementation of the laser assembly described with reference to FIG. 5. By way of example, the back-side emission laser is a VCSEL 760. The VCSEL 760 may be formed in an epitaxial stack 702 on a substrate 704 (e.g., a GaAs substrate). The epitaxial stack 702 may define a first DBR 706, a second DBR 708, and an active region 710 (e.g., a MQW structure). The active region 710 may be disposed between the first DBR 706 and the second DBR 708. The second DBR 708 is optional and, if provided, the second DBR 708 may be weaker than the first DBR 706 (e.g., as described with reference to FIG. 5). In some embodiments, the second DBR 708 may only be provided as a current spreading layer and means for current injection.

The active region 710 may be disposed in a resonant cavity 762 extending between a reflector 738 (a first reflector) and the first DBR 706 (a second reflector). The resonant cavity 762 includes the back-side resonant cavity extension 758 (the resonant cavity extension 758).

The resonant cavity extension 758 may be defined by the substrate 704, and may extend between the surface 766 and the surface 740. The reflector 738 may be disposed on the first side of the substrate 704, and in some embodiments may be deposited on the surface 740 (i.e., the emission surface) of the substrate 704. When deposited on the substrate 704, and in some embodiments, the reflector 738 may include at least one of SiO₂ or SiN (e.g., one or more layers of SiO₂ and/or SiN). The reflector 738 may be configured to reflect at least one wavelength of electromagnetic radiation generated by the active region 710. In some embodiments, the reflector 738 may include one or more layers of dielectric or metal. In some embodiments, the reflector 738 may be constructed as a DBR.

In some embodiments, a single epitaxial stack 702 may be formed on the substrate 704, and then one or more trenches 712, 714 may be etched into (or otherwise formed in) the epitaxial stack 702 to form a set of mesas 716, 718, 720 on the substrate 704. In this manner, each of the mesas 716, 718, 720 may have a same or similar construction and properties. By way of example, three mesas 716, 718, 720 are shown. In other embodiments, more or fewer mesas may be formed. In some embodiments, different mesas may be formed as different epitaxial stacks and/or using different process steps. In some embodiments, some of the mesas may not be formed as epitaxial stacks and may be formed in other ways (e.g., as monolithic blocks of a material).

Some or all of the mesas formed on a substrate may be operable as VCSELs (i.e., lasers). However, in some embodiments, some of the mesas may not be electrically connected to other circuits and may not be operable (or may not be operable as lasers). In FIG. 7, mesa 718 is operable as a VCSEL 760 and mesas 716 and 720 are not operable and only provide mechanical support for mounting the VCSEL 760 to another structure, such as a substrate 742 containing contact pads, conductors, and/or circuitry (e.g., LDD circuitry).

As further shown in FIG. 7, one or more layers of dielectric 722, such as one or more layers of SiN or SiO₂, may be deposited on a portion of the substrate 704 between the mesa 716 and the mesa 718, and optionally on a portion of the substrate 704 between the mesa 718 and the mesa 720. The one or more layers of dielectric 722 may also be deposited on walls of the mesas 716, 718, 720. The one or more layers of dielectric 722 may insulate a cathode 724 and an anode 728 of the VCSEL 760 from the mesas 716 and 720. The cathode 724 (e.g., one or more layers of metal) may extend from an upper surface 726 of the mesa 716, along a side of the mesa 716, over the one or more layers of dielectric 722, along a side of the mesa 718, and onto a surface of the epitaxial stack 702 (and more specifically, onto the second DBR 708, on a side of the second DBR 708 opposite the active region 710). The anode 728 (e.g., another one or more layers of metal) may extend from an upper surface 730 of the mesa 720, along a side of the mesa 720, and onto a doped layer 732 of the substrate 704. The doped layer 732 may be conductive, and may extend under the mesa 718 and contact the epitaxial stack 702 of the VCSEL 760. In some embodiments, the doped layer 732 may extend under all of the mesas 716, 718, 720. If the VCSEL 760 is included in an array of VCSELs, the anode 728 may be shared by all of the VCSELs in the array of VCSELs, and each VCSEL may be provided with its own cathode.

In some embodiments, gold (Au) plating 734 may be applied to a portion of the cathode 724 and a portion of the anode 728, to improve the conductivity of the cathode 724 and the anode 728.

The VCSEL 760 may be used as a back-side emission laser, and may emit a primary emission through the substrate 704. In some embodiments, an anti-reflective coating (e.g., one or more layers of SiN and/or SiO₂) may be formed on the reflector 738. Optionally, a lens 764 or other optical element(s) may be defined in, or disposed (e.g., deposited) on, the emission surface 740, and/or a lens (e.g., a dielectric lens) or other optical element(s) may be positioned to receive at least one wavelength of electromagnetic radiation generated by the active region 710 of the VCSEL 760 and emitted through the substrate 704, as described with reference to FIG. 5.

A photodetector 770 (e.g., a photodiode) may be formed on or in the substrate 742, and the substrate 742 may be bonded to an additional substrate 744. In some embodiments, each of the substrates 742. 744 may be a Si substrate. In other embodiments, one or both of the substrates 742, 744 may take other forms. In some embodiments, the additional substrate 744 may include conductors and/or circuitry 768 (e.g., LDD circuitry).

A first solder bump 746 (e.g., a first gold solder bump) may mechanically and electrically attach the cathode 724 to a first contact pad 748 on the substrate 742. The first contact pad 748 may be coupled to a first conductor on or in the substrate 742. A second solder bump 750 (e.g., a second gold solder bump) may mechanically and electrically attach the anode 728 to a second contact pad 752 on the substrate 742. The second contact pad 752 may be coupled to a second conductor on or in the substrate 742.

The photodetector 770 may be positioned to receive a secondary emission of electromagnetic radiation from the VCSEL 760 (e.g., an emission made through the first DBR 706).

A dielectric fill material 754 may be disposed around the mesas 716, 718, 720, between the substrate 704 and the substrate 742. The dielectric fill material 754 may be transparent, or partially transparent, to at least a wavelength of electromagnetic radiation generated by the active region 710. The dielectric fill material 754 may provide further mechanical stability to the VCSEL 760.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. A laser assembly, comprising:
a set of one or more substrates having a first surface opposite a second surface, the set of one or more substrates defining a resonant cavity extension, the resonant cavity extension extending into the set of one or more substrates from an opening in the first surface;
a first reflector disposed within the resonant cavity extension and configured to reflect at least one wavelength of electromagnetic radiation;
a laser having an active region configured to generate the at least one wavelength of electromagnetic radiation; and
a second reflector, the active region disposed in a resonant cavity extending between the first reflector and the second reflector, and the resonant cavity including the resonant cavity extension.

2. The laser assembly of claim 1, wherein:
the set of one or more substrates include a first substrate and a second substrate;
the first reflector is disposed within the first substrate; and
the second substrate defines the first surface and the opening.

3. The laser assembly of claim 2, wherein the first reflector comprises at least one layer of dielectric or metal.

4. The laser assembly of claim 2, wherein:
the first substrate comprises a first silicon substrate; and
the second substrate comprises a second silicon substrate.

5. The laser assembly of claim 2, wherein the first substrate is bonded to the second substrate by an oxide-to-oxide bond.

6. The laser assembly of claim 1, further comprising a polymer filling the resonant cavity extension.

7. The laser assembly of claim 1, wherein the set of substrates consists of a single substrate.

8. A laser assembly, comprising:
a set of one or more silicon substrates defining a resonant cavity extension;
a reflector disposed in the resonant cavity extension;
a gallium arsenide (GaAs) substrate;
an epitaxial stack on the GaAs substrate, the epitaxial stack including,
a distributed Bragg reflector (DBR); and
an active region of a laser, the active region of the laser disposed within a resonant cavity including the resonant cavity extension and extending between the reflector and the DBR.

9. The laser assembly of claim 8, wherein:
the DBR is a first DBR;
the epitaxial stack further comprises a second DBR, positioned between the active region and the reflector; and
the second DBR is weaker than the reflector.

10. The laser assembly of claim 8, wherein a structure including the GaAs substrate and the epitaxial stack is bonded to the set of one or more silicon substrates.

11. The laser assembly of claim 8, further comprising:
a set of mesas disposed on the GaAs substrate; wherein, at least one mesa of the set of mesas includes the epitaxial stack; and
the set of mesas is mechanically attached to a silicon substrate of the set of one or more silicon substrates.

12. The laser assembly of claim 11, further comprising a set of solder bumps mechanically and electrically attaching the set of mesas to the silicon substrate.

13. The laser assembly of claim 11, further comprising a set of conductors disposed on or in the silicon substrate and electrically connected to an anode and a cathode of the laser.

14. The laser assembly of claim 8, wherein the resonant cavity extension is filled with air.

15. A laser assembly, comprising:
a substrate having a first surface on a first side and a second surface on a second side;
a reflector disposed on the first side, on or offset from the first surface;
an epitaxial stack on the substrate, the epitaxial stack defining a set of mesas, a mesa of the set of mesas including,
a distributed Bragg reflector (DBR); and
an active region of a laser, the active region of the laser disposed within a resonant cavity extending between the reflector and the DBR;
a silicon substrate, the set of mesas mechanically attached to the silicon substrate; and
a set of conductors disposed on or in the silicon substrate and electrically connected to an anode and a cathode of the laser.

16. The laser assembly of claim 15, wherein:
the DBR is a first DBR;
the epitaxial stack further comprises a second DBR, positioned between the active region and the reflector; and
the second DBR is weaker than the reflector.

17. The laser assembly of claim 15, wherein the reflector comprises at least one of silicon dioxide (SiO₂) or silicon nitride (SiN).

18. The laser assembly of claim 15, wherein the reflector comprises metal.

19. The laser assembly of claim 15, wherein the substrate comprises a gallium arsenide (GaAs) substrate.

20. The laser assembly of claim 15, wherein:
the mesa is a first mesa; and
the set of mesas includes a second mesa, the second mesa inoperable as a laser.
